(19) United States
(12) Patent Application Publication
(10) Pub. No.: US 2017/0243610 A1
(43) Pub. Date: Aug. 24, 2017

(54) ULTRA-THIN CORROSION RESISTANT HARD OVERCOAT FOR HARD DISK MEDIA

(71) Applicant: Intevac, Inc., Santa Clara, CA (US)

(72) Inventor: Terry Bluck, Santa Clara, CA (US)

(21) Appl. No.: 15/437,375

(22) Filed: Feb. 20, 2017

Related U.S. Application Data
(60) Provisional application No. 62/297,700, filed on Feb. 19, 2016.

(51) Int. Cl. G11B 5/72; G11B 5/851; H01J 37/317; G11B 5/84

(52) U.S. Cl. CPC G11B 5/722; G11B 5/8408; G11B 5/851; H01J 37/3171; H01J 37/3178; H01J 2237/31705

(57) ABSTRACT

A magnetic media disk is fabricated by depositing magnetic layers over the disk, then depositing protective later over the magnetic layer, and then performing ion implant process to implant ions into the protective coating. A system for performing the ion implant of the magnetic media disk includes two ion implant chambers. During operation one chamber performs ion implant and one chamber performs chamber cleaning by maintaining inside a plasma of cleaning gas without a disk present inside the chamber.

### RELATED APPLICATION

This application claims priority benefit from U.S. Provisional Application Ser. No. 62/297,700, filed on Feb. 19, 2016, the disclosure of which is incorporated herein by reference in its entirety.

### BACKGROUND

1. Field

This disclosure relates to the fabrication of hard disks used for magnetic media recording, or hard disk drives (HDD). More specifically, it relates to the protection layer provided on top of the magnetic layers.

2. Related Art and Problem being Solved

For hard drive manufacturers the gap between the read/write heads and the magnetic layers is very important. Smaller gaps mean better signal to noise ratios and therefore higher areal densities. Generally protective overcoat are made by depositing a carbon film over the magnetic layer. Since the 1990's the carbon film thickness has been reduced from more than 100 angstrom to about 22 angstrom. This has happened due to the improved carbon properties of the protective overcoat. Greater density and SP3 bond ratios results in improved protective layer over the magnetic layers. However, the improvements have stopped because there has not been a way on the HDD media to improve the carbon properties that does not have fatal flaws such as excessive particles, lack of edge coverage, or deposition rates that are too slow for commercial-scale fabrication.

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

An improved protective coating is provided by depositing a diamond-like carbon (DLC) coating and then bombarding the DLC coating using ion implant. In disclosed embodiments, the ion species are selected to harden and densify the film. In other embodiments, the ion species are selected so that some of the species will implant deeper into the DLC layer, while other species would remain close to the surface. In yet other embodiments, the ion species are selected to also provide hydrophobic or oleophobic properties to the top surface. In further embodiments, the ion species and ion implant energy are selected to include partial deposition of ions on the surface of the DLC.

According to disclosed embodiments, a magnetic hard disk used for data storage is provided, comprising: a disk-shaped substrate; a plurality of magnetic layers formed on the substrate; and a protective layer having molecules interconnected by inter-molecules bonds and implanted ions positioned among the inter-connected molecules but having no bonds to the interconnected molecules. The magnetic hard disk may further comprise an implanted hydrophobic layer. The protective layer may comprise a diamond-like carbon (DLC) and the implanted ion may be selected from one or more of: CxHy, CxFy, BxFy, NxFy and N2. The hydrophobic layer may comprise implanted CxFy, NxFy or BxFy. The DLC layer may also cover vertical edges at the inner and outer edges of the disk. The implanted ions may comprise deeply implanted ions selected from CxHy or N2, and surface implanted ions selected from CxFy, BxFy and NxFy.

According to other embodiments, a method for fabricating a hard disk for magnetic media hard disk drive is disclosed, comprising: depositing a magnetic film stack on a disk-shaped substrate; depositing a diamond-like carbon (DLC) coating over the magnetic film stack; implanting ions into the DLC coating. The implanting may comprise implanting ion species selected from one or more of: CxHy, CxFy, BxFy, NxFy and N2. The implanting ions may comprise deeply implanting ions of one or more of CxHy or N2, and surface implanting ions selected from one or more of CxFy, BxFy and NxFy. The method may further comprise forming hydrophobic layer by ion implant process over the DLC. Forming hydrophobic layer may comprise ion implanting ions selected from one or more of CxFy, BxFy and NxFy, or depositing a hydrophobic layer by ion implantation process using ions selected from one or more of CxFy, BxFy and NxFy.

Further aspects involve a system for performing ion implant, comprising: a first ion implant chamber, a second implant chamber, and a high vacuum isolation valves in between the first and second ion implant chambers; a process gas source coupled to the first and second ion implant chambers through a first toggle valve having its open position selectively flowing process gas to only one of the first and second ion implant chambers at a given position; a cleaning gas source coupled to the first and second ion implant chambers through a second toggle valve having its open position selectively flowing cleaning gas to only one of the first and second ion implant chambers at a given position; wherein the first and second toggle valve are configured to operate exclusively counter-synchronously. The system may further comprise a controller programmed to alternate ion implant processing between the first and second ion implant chambers and perform chamber cleaning in the other of the first and second ion implant chamber. The process gas source include gas selected from CxHy, CxFy, BxFy, NxFy and N2, while the cleaning gas comprises oxygen. Each of the first and second implant chambers may comprise: a plasma cage;

an implant chamber; a grid positioned in an opening between the plasma cage and the implant chamber; and biased electrodes positioned inside the plasma cage. The biased electrodes comprise a first and a second electrodes, one biased to a positive potential and the other biased to a negative potential.

According to further aspects, an ion implant chamber is provided, comprising: a processing chamber having transport track for transport a substrate carrier, thereby defining a substrate position within the processing chamber; a plasma cage having a window enabling fluid communication between the plasma cage and the processing chamber; a grid assembly positioned in the window, thereby confining the plasma inside the plasma cage; and a biased electrode assembly positioned inside the processing chamber between the grid and the substrate position. The biased electrode assembly may comprise a first and a second electrode positioned opposite each other, wherein one of the first and a second electrode is biased positively and the other of the first and a second electrode is biased negatively.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

One or more embodiments of the present invention are illustrated by way of example and not limitation in the figures of the accompanying drawings, in which like references indicate similar elements and in which:

FIG. 1 is a schematic of molecular structure of DLC according to the prior art;

FIG. 2 is a schematic of molecular structure of DLC according to an embodiment of the invention;

FIG. 3 is an isometric view of a hard disk according to an embodiment of the invention;

FIG. 4 is a cross-section along lines A-A of FIG. 3;

FIG. 5 is a schematic of a processing system configured for fabricating DLC according to an embodiment of the invention.

FIG. 6 is a schematic of a processing chamber according to one embodiment.

### DETAILED DESCRIPTION

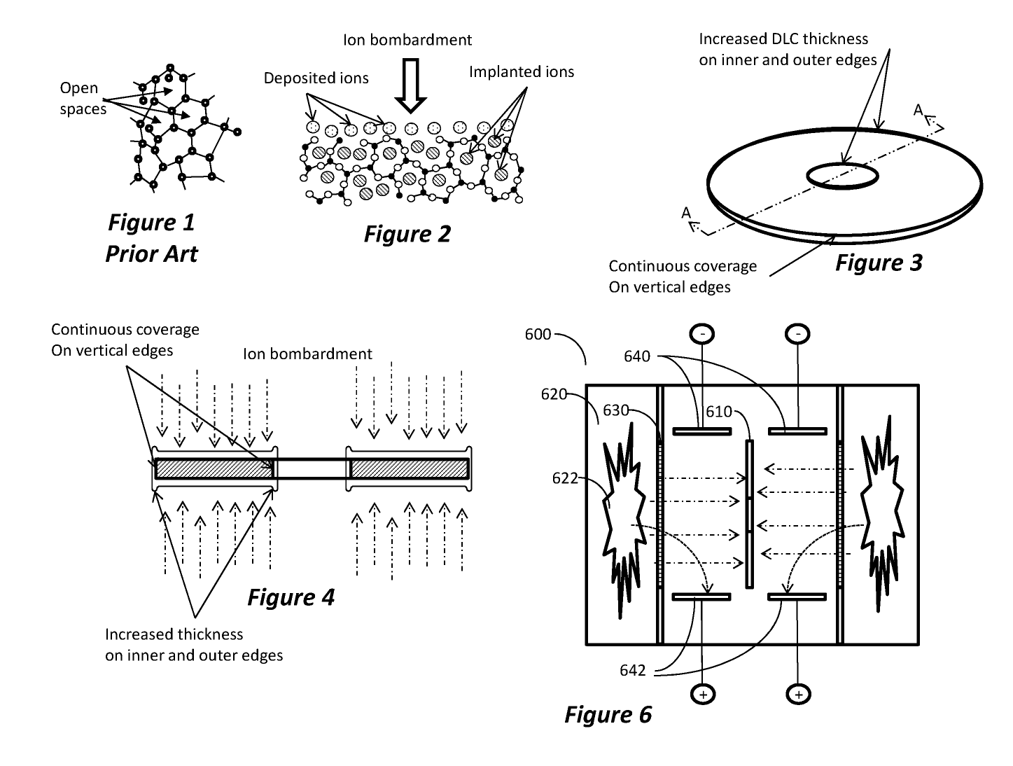

FIG. 1 is a schematic of molecular structure of DLC according to the prior art. Circles designate DLC molecules, while lines designate inter-molecular bonding. As shown in FIG. 1, the molecular structure of DLC has many “voids” or open spaces. According to embodiments of the invention, ion implant is used to physically “fill” these holes with other elements, without making inter-molecular bonds. The ion implantation hardens and densifies the film by introducing stresses into the existing molecular structure.

FIG. 2 is a schematic of molecular structure of DLC according to an embodiment of the invention. Blank and filled circles designate DLC molecule while lines designate inter-molecular bonding of the DLC molecules. As illustrated in FIG. 2, energetic ions bombard the surface of the DLC that was deposited beforehand. The ions embed (patterned circles) into voids of the existing film, increasing the density and introducing compressive stress, thus enhancing the mechanical properties of the film. The ions are introduced in a physical process, such that generally the ions do not form new bonds with the DLC molecules. It is possible, though, that due to heat generated during the implantation process some self-annealing will occur and some implanted ions will develop new bonds, yet many implanted ions will not form new bonds and will just exert stress on existing DLC bonds. Notably, the implantation is performed only to modify the mechanical properties of the DLC film, as opposed to cases where the ion implantation is done to dope the material, thus changing its electrical properties. Therefore, in this embodiment the process is designed to cause embedded ions to simply occupy available spaces within the molecular structure of the DLC, without forming bonds with the molecules of the DLC.

In certain embodiments the surface properties of the DLC film can also be modified to create a hydrophobic surface. This is illustrated by the implanted molecules shown in dotted circles. In this case, the ions are implanted close to the surface of the DLC film, or are deposited using ion implantation process, to generate a hydrophobic surface. The ions are implanted at a very low energy, so that they are present mostly, if not exclusively, on or near the surface of the disk.

Due to the deposition process, the deposited carbon film has increased thickness at the edges and a continuous coating on the vertical surfaces of the disk. FIG. 3 illustrates a hard disk, while FIG. 4 is a cross section of the hard disk of FIG. 3 along lines A-A. The process starts by forming the magnetic layers, e.g., by standard deposition such as sputtering deposition. Then DLC carbon overcoating is deposited at the desired thickness using standard DLC deposition techniques. As shown in FIGS. 3 and 4, the DLC thickness is higher at the outer and inner diameter edges of the disk. Also, coating is continuous around the vertical walls of the inner and outer diameters of the disk, so as to provide corrosion protection. Thereafter the disk is inserted into an ion implanter. The DLC is implanted by an ion beam operating at an energy level so as to densify the carbon layer while not damaging the underlying magnetic film. This energy will be species dependent (i.e., based upon the size of the implanted ions). Smaller ions will require less energy than larger ions. Consequently, for a given implanter energy, smaller ions will embed deeper into the DLC than larger ions. In one embodiment, the ion beam has a diameter at least as large as the outer diameter of the disk, so that the entire surface of the disk is implanted simultaneously. In one embodiment the implantation is done on both sides of the substrate simultaneously. In one embodiment the implanter employs remote plasma having a gridded opening, such that plasma cannot reach the surface of the disk, but ions from the plasma can pass through the grid and reach and be implanted in the DLC on the surface of the disk.

Also, in disclosed embodiments using the gridded plasma chamber the implanted ions are not mass analyzed, such that all of the molecule species present in the plasma can be implanted. An advantage of non-mass analyzed ion implantation is that the ion implantation depth profile is rather broad as compared to mass analyzed implant. As a result, the atomic concentration profile is very high at very near surface and then tails off with depth, such that the top surface of the disk becomes the strongest mechanically, while the remaining bulk of the disk is not affected by the implant.

The implantation gas could be from any one of the following: CxHy, CxFy, BxFy, NxFy and N2. For deeper penetration, it is beneficial to use CxHy or N2 as these are smaller molecules that will implant deeper into the DLC layer. However, for improved hydrophobic property of the surface, it is beneficial to use one of CxFy, BxFy, NxFy, as the fluorine will enhance the hydrophobic property, and the molecule is relatively large, such that it will not penetrate deeply and will remain close to the surface. Of course, in some embodiments a first implant process uses the smaller molecules, e.g., CxHy or N2, for deeper implant and enhanced mechanical properties of the DLC, followed by implant of one of CxFy, BxFy, NxFy, for improving the hydrophobic properties of the surface. Also, the implanting energy may be controlled so as to first cause physical implant of ions, and thereafter reducing the energy to perform deposition of fluorinated ions on the surface—using ion implant processing—and thereby form a hydrophobic layer.

As explained above, the implantation causes an increase in the density of the DLC film. In some cases the subsequent implantation step may result in a denser thinner film than the starting film. In this case the desired starting thickness would be greater than the final thickness. In some cases the subsequent Implantation step may result in a denser thicker film than the starting film, due, e.g., to deposition by ion implant. In this case the desired starting thickness would be less than the final thickness. In some cases the subsequent Implantation step may result in a denser film without a change in thickness, e.g., embedded molecules are relatively small and introduce only stress within the DLC molecular structure. In this case the desired starting thickness would be the final thickness.

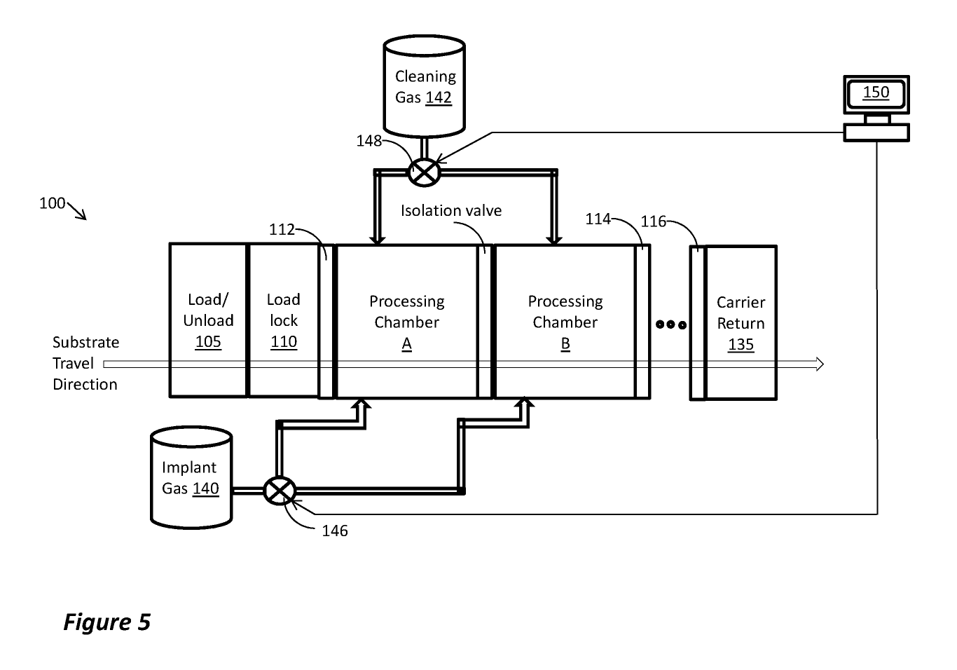

FIG. 5 illustrates an embodiment of a system for ion implanting of hard disks. In this embodiment there are two process stations for ion implantation with high vacuum isolation valves in between. The process occurs in one station while cleaning plasma is run in the other so as to clean the interior of the chamber. The chambers then alternate every other substrate. This keeps the throughput high and keeps the chambers clean, to ensure low particles generation during the implantation process.

This embodiment is especially beneficial for ion implant using a hydrocarbon gas, since there would be deposition on the walls and grids. In order to prevent this from creating particles, the carbon build up must be stripped by running oxygen plasma inside the chamber. The substrate cannot be in the chamber during the oxygen plasma. So there are two identical chambers which alternate between Implantation and Clean. The simultaneous operation in the two chambers is considered as one cycle. Process gas supply 140 is coupled to both chambers via a toggle valve 146. Cleaning gas supply 142 is coupled to both chambers via toggle valve 148. In operation, the two toggle switches 146 and 148 are counter-synchronized. That is, when one valve is open for one chamber, the other valve if closed for that chamber. For example, when toggle valve 146 is open for chamber A and closed for chamber B, toggle valve 148 is closed for chamber A and open for chamber B.

The substrate is only in the chamber that performs implantation process. Say there are two chambers (A & B) adjacent to each other with A being the first chamber reached as the substrate travels thru the system. Then, on the even cycle the substrate moves into chamber A and is implanted while chamber B is stripped. On the next machine cycle the processed substrate exits chamber A and passes through to exit chamber B as well. A fresh substrate to be processed moves through chamber A and stops in chamber B for processing. Chamber A remains empty. Chamber B performs the Implant process while chamber A is stripped. The cycle repeats continuously.

A controller 150 controls the operation of the system. It directs the transportation of the substrates and commands the ignition and maintenance of plasma within the chambers. The controller 150 also controls the valves 146 and 148.

FIG. 6 illustrates an embodiment wherein the disk 610 is implanted simultaneously from both sides, although the features illustrated in FIG. 6 may be implemented in a chamber wherein the disk 610 is implanted only on one side. Chamber 600 has a plasma cage 620 wherein plasma 622 is maintained. As ion species are generated within plasma 622, the ions pass through grid 630 towards disk 610, as illustrated by the dash-dot arrows. The size of the grid 630 is at least as large as the size of the disk 610.

During processing large particles may form and may land on the disk 610, causing defects. In order to avoid such an occurrence, in this embodiment opposing electrodes 640 and 642 are placed in the path between the grid and the disk. One electrode is biased to positive potential while the other biased to negative potential. Consequently, when a particle enters the area between the grid 630 and disk 610, it would be attracted to one of the electrodes 640 or 642, depending on the charge on the particle, as illustrated by the curved dashed arrow.

Specifically, as illustrated in FIG. 6, the disk 610 is transported within the processing section of chamber 600, e.g., by a carrier travelling on tracks or rails (not shown for clarity). The place occupied by the substrate is defined as a substrate position (within the processing section). The ion travel section is defined as the space between the grid 630 and the substrate position. A boundary of the ion travel section is defined by imaginary cylinder have a diameter equals to the outer diameter of the disk, and positioned between the grid 630 and the disk position. An electrode assembly, in FIG. 6 comprising two electrodes 640 and 642, is situated between the grid 630 and the substrate position, but outside of the ion travel section, i.e., beyond the imaginary cylinder having the same diameter as that of the disk 610. One electrode is biased positively, while the other is biased negatively. Thus, any particles traveling within the ion travel section are attracted to the electrodes and will not land on the disk 610.

While this invention has been discussed in terms of exemplary embodiments of specific materials, and specific steps, it should be understood by those skilled in the art that variations of these specific examples may be made and/or used and that such structures and methods will follow from the understanding imparted by the practices described and illustrated as well as the discussions of operations as to facilitate modifications that may be made without departing from the scope of the invention defined by the appended claims.

1. A magnetic hard disk used for data storage, comprising:
a disk-shaped substrate;
a plurality of magnetic layers formed on the substrate;
a protective layer having molecules interconnected by inter-molecules bonds and implanted ions positioned among the inter-connected molecules but having no bonds to the interconnected molecules.

2. The magnetic hard disk of claim 1, further comprising an implanted hydrophobic layer.

3. The magnetic hard disk of claim 1, wherein the protective layer comprises a diamond-like carbon (DLC) and the implanted ion are selected from one or more of: CxHy, CxFy, BxFy, NxFy and N2.

4. The magnetic hard disk of claim 2, wherein the hydrophobic layer comprises implanted CxFy, NxFy or BxFy.

5. The magnetic hard disk of claim 3, wherein the DLC layer also covers vertical edges at the inner and outer edges of the disk.

6. The magnetic hard disk of claim 1, wherein the implanted ions comprise deeply implanted ions selected from CxHy or N2, and surface implanted ions selected from CxFy, BxFy and NxFy.

7. A method for fabricating a hard disk for magnetic media hard disk drive, comprising:
depositing a magnetic film stack on a disk-shaped substrate;
depositing a diamond-like carbon (DLC) coating over the magnetic film stack;
implanting ions into the DLC coating.

8. The method of claim 7, wherein the implanting comprises using ion species selected from one or more of: CxHy, CxFy, BxFy, NxFy and N2.

9. The method of claim 7, wherein implanting ions comprises deeply implanting ions of one or more of CxHy or N2, and surface implanting ions selected from one or more of CxFy, BxFy and NxFy.

10. The method of claim 7, further comprising forming hydrophobic layer by ion implant process over the DLC.

11. The method of claim 10, wherein forming hydrophobic layer comprises ion implanting ions selected from one or more of CxFy, BxFy and NxFy.

12. The method of claim 10, wherein forming hydrophobic layer comprises depositing a hydrophobic layer by ion implantation process using ions selected from one or more of CxFy, BxFy and NxFy.

13. A system for performing ion implant, comprising:
a first ion implant chamber, a second implant chamber, and a high vacuum isolation valves in between the first and second ion implant chambers; a process gas source coupled to the first and second ion implant chambers through a first toggle valve having its open position selectively flowing process gas to only one of the first and second ion implant chambers at a given position; a cleaning gas source coupled to the first and second ion implant chambers through a second toggle valve having its open position selectively flowing cleaning gas to only one of the first and second ion implant chambers at a given position; wherein the first and second toggle valve are configured to operate exclusively counter-synchronously.

14. The system of claim 13, further comprising a controller programmed to alternate ion implant processing between the first and second ion implant chambers and perform chamber cleaning in the other of the first and second ion implant chamber.

15. The system of claim 13, wherein the process gas source includes gas selected from CxHy, CxFy, BxFy, NxFy and N2.

16. The system of claim 15, wherein the cleaning gas comprises oxygen.

17. The system of claim 13, wherein each of the first and second implant chambers comprises:
a plasma cage;
an implant chamber;
a grid positioned in an opening between the plasma cage and the implant chamber;
biased electrodes positioned inside the plasma cage.

18. The system of claim 17, wherein the biased electrode comprise a first and a second electrodes, one biased to a positive potential and the other biased to a negative potential.

19. An ion implant chamber, comprising:
a processing chamber having transport track for transport a substrate carrier, thereby defining a substrate position within the processing chamber;
a plasma cage having a window enabling fluid communication between the plasma cage and the processing chamber;
a grid assembly positioned in the window, thereby confining the plasma inside the plasma cage;
a biased electrode assembly positioned inside the processing chamber between the grid and the substrate position.

20. The ion implant chamber of claim 19, wherein the biased electrode assembly comprises a first and a second electrode positioned opposite each other, wherein one of the first and a second electrode is biased positively and the other of the first and a second electrode is biased negatively.
